(19) United States
(12) Patent Application Publication
(10) Pub. No.: US 2026/0089898 A1
(43) Pub. Date: Mar. 26, 2026

(54) COOLING APPARATUS FOR POWER MODULES

(71) Applicant: SEMICONDUCTOR COMPONENTS INDUSTRIES, LLC, Scottsdale, AZ (US)

(72) Inventors: Roveendra PAUL, Dublin, CA (US); Moonseok HONG, Seoul (KR); Hyunseok LIM, Seongnam-si (KR)

(73) Assignee: SEMICONDUCTOR COMPONENTS INDUSTRIES, LLC, Scottsdale, AZ (US)

(21) Appl. No.: 19/327,748

(22) Filed: Sep. 12, 2025

Related U.S. Application Data
(60) Provisional application No. 63/698,837, filed on Sep. 25, 2024.

(51) Int. Cl. H05K 7/20

(52) U.S. Cl. CPC H05K 7/20927

(57) ABSTRACT

The cooling of power modules used in high-power systems, such as three-phase inverters, may require a cooling apparatus that is heavier than desired for some applications, such as electric vehicles. A cooling apparatus is disclosed that can provide sufficient cooling in a weight-reduced package. Additionally, assembly methods are disclosed that make the cooling apparatus more robust to shocks and vibrations, which may be experienced by electric vehicles.

### CROSS-REFERENCE TO RELATED APPLICATION

This application claims the benefit of U.S. Provisional Application No. 63/698,837, filed on Sep. 25, 2024, which is hereby incorporated by reference in its entirety.

### FIELD OF THE DISCLOSURE

The disclosure is related to electronic cooling and more specifically to a cooling apparatus (i.e., cooler) for one or more power modules.

### BACKGROUND

Power modules may be used in a system for an electric vehicle. For example, a power module may be a half-bridge circuit configured to output an alternating current (AC) signal, and a traction inverter for an electric vehicle may use three power modules to generate 3-phase AC power that can be used to drive an electric motor. The switching of the half-bridge circuit, which may be carried out using power transistors, can operate at power levels in the kilowatt range. As a result, the heat generated by these systems can require active liquid cooling for its dissipation.

### SUMMARY

A cooling apparatus is disclosed that can provide the thermal dissipation to prevent power modules from overheating without being too bulky or expensive. Additionally, the cooler uses an adhesive (e.g., sealant-adhesive)) to achieve the mechanical strength required to withstand the potential shock and vibrations associated with vehicles.

In some aspects, the techniques described herein relate to a cooling apparatus for a power module, the cooling apparatus including: a body including: a basin having a bottom surface offset from a top surface by a depth; and a cover coupled (e.g., adhered) to the top surface of the body by an adhesive (e.g., sealant-adhesive), the cover including: a first material layer facing the basin; and a second material layer facing the power module.

In some aspects, the techniques described herein relate to a three-phase inverter including: a first power module; a second power module; a third power module; and a cooler coupled to the first power module, the second power module, and the third power module, the cooler including: a body including: a basin having a bottom surface offset from a top surface by a depth; and a groove in the top surface surrounding the basin; and a cover coupled (e.g., adhered) to the top surface of the body by an adhesive (e.g., sealant-adhesive) disposed in the groove, the cover including: a first metal layer facing the basin; and a second metal layer facing the first power module, the second power module, and the third power module.

In some aspects, the techniques described herein relate to a method including: attaching a power module to a copper layer of a cover, the cover including the copper layer at a top side facing the power module and an aluminum layer at a bottom side opposite to the top side; dispensing adhesive (e.g., sealant-adhesive) into a groove in a top surface of a body, the groove surrounding a basin defined by the body, the basin having a bottom surface offset from the top surface by a depth; and adhering the bottom side of cover to the top surface of the body with the adhesive (e.g., sealant-adhesive) so that the aluminum layer faces the basin.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a perspective view of a system including power modules and a cooling apparatus according to a possible implementation of the present disclosure.

FIG. 2 is an exploded, perspective view of a cooling apparatus according to a possible implementation of the present disclosure.

FIG. 3A is an exploded, side view of a portion of a cooling apparatus according to a possible implementation of the present disclosure.

FIG. 3B is a cross-sectional view of the cover shown in FIG. 3A according to a possible implementation of the present disclosure.

FIG. 3C is another cross-sectional view of the cover shown in FIG. 3A according to a possible implementation of the present disclosure.

FIG. 4 is a cross-sectional view of the cooling apparatus with an inset illustrating details of a groove for adhesive (e.g., sealant-adhesive) according to a possible implementation of the present disclosure.

FIG. 5A is a side-view of a power module according to a possible implementation of the present disclosure.

FIG. 5B illustrates the placement of the power module on the cooling apparatus according to a possible implementation of the present disclosure.

FIG. 6 visually illustrates a method for assembling a three-phase inverter with a cooling apparatus according to a possible implementation of the present disclosure.

FIG. 7 is a flowchart of a method for assembling a three-phase inverter according to a possible implementation of the present disclosure.

The components in the drawings are not necessarily to scale relative to each other. Like reference numerals designate corresponding parts throughout the several views.

### DETAILED DESCRIPTION

Packaging for power electronics may include a cooling apparatus (i.e., cooler) to provide thermal management for a power module (or power modules). For example, power modules may be attached to a cooler so that heat generated by the circuitry of the power modules (e.g., IGBT, MOSFET, diodes, inductors, transformers, etc.) can be absorbed by the cooler. The amount/rate of the absorption may be based on the thermal conductivity and the mass of the cooler, and fluid (e.g., water, dielectric fluid) may be pumped through the cooler to enhance the cooling.

As cooling requirements increase, a conventional single material (e.g., copper) cooler may become too heavy and too expensive for some applications, such as electric vehicles. The present disclosure addresses this first technical problem with a cooling apparatus that has a cover, which includes different materials to balance thermal conductivity and weight.

Electric vehicles may experience shocks and vibrations in an accident that are higher than other applications. A second technical problem with conventional coolers, which use only fasteners, is their ability to withstand car accidents without leaking at a seam formed by the cover. The present disclosure addresses this second technical problem with a cooling apparatus that has a cover coupled (e.g., adhered) to a body by an adhesive (e.g., sealant-adhesive) to make the cooler more mechanically robust.

The disclosed cooling apparatus may be used with at least one power module. As used herein a power module may refer to a semiconductor package that includes at least one semiconductor die. In a possible implementation, a semiconductor die included in a power module can include a transistor, such as a metal-oxide-semiconductor field-effect transistor (MOSFET) or an insulated-gate bipolar transistor (IGBT).

The semiconductor die may be implemented using a single semiconductor material, such as silicon (Si). The semiconductor die may also be implemented using a compound semiconductor material. The compound semiconductor material can be a combination of elements from group III of the periodic table (e.g., aluminum, gallium, indium, etc.) with elements from group V of the periodic table (e.g., nitrogen, arsenic, etc.). In one possible implementation, a die of the power module may be implemented using gallium nitride (GaN). The semiconductor die may also be implemented as a chemical compound including silicon to improve its performance. For example, dies implemented using silicon carbide (SiC) may have a wide-bandgap, making them suitable for high-power, high-temperature, and high-frequency devices (e.g., transistors).

A power module may include multiple semiconductor dies, which can be electrically coupled together to form a circuit. In a possible implementation, the power module includes a half-bridge circuit consisting of two transistors connected in series across a positive and negative input. Each of the two transistors may be implemented as a semiconductor die. The two semiconductor dies may be coupled to a substrate for electrical connection and cooling. The substrate includes conductors (e.g., traces, pads, wires, etc.) to form the electrical connections required for the half-bridge circuit and to provide connection points for external connection. The conductors may be implemented using a metal (e.g., gold, silver, aluminum, etc.), and the conductors may form patterns (e.g., traces, pads) on a surface (e.g., top surface, bottom surface) of the substrate or on interlayers of the substrate.

In a possible implementation, the substrate of a power module may be implemented as a direct bonded metal (DBM) substrate that includes an insulating layer between two metal layers. For example, a direct bonded copper (DBC) substrate can include the insulating layer disposed between a first copper layer and a second copper layer. The insulating layer can be, for example, a ceramic layer. In some implementations, the ceramic layer is, or includes, a ceramic material, such as alumina (Al₂O₃) or aluminum nitride (AlN)).

In some implementations, the first metal layer and/or the second metal layer can be coupled to a heat sink. In a possible implementation, a portion of the first metal layer or the second metal layer can be exposed through a molding compound containing the dies of the power module, and the portion may be coupled to the cooling apparatus.

The molding compound may function as a protective outer shell made for the power module. In some implementations, the molding compound (i.e., molding material, encapsulation material) is a non-conducting material, such as an epoxy, which can be formed (applied, etc.) using a transfer molding process or a compression molding process. In some implementations, the molding compound can include a separate plastic housing that is included in the power module assembly.

The power module may include one or more wire bonds to couple the semiconductor die (or dies) to a lead frame. The lead frame can include pins, terminals, tabs, or pads to couple the power module externally. In a possible implementation, one or more of the wire bonds may be replaced with a conductive clip. The conductive clip can be coupled to another component (e.g., an attach pad, a lead frame, a semiconductor die, etc.) using a soldering process, a sintering process, or a metal-to-metal bonding process.

The soldering process can include joining two surfaces (e.g., metal surfaces) together using a molten metal alloy, which can include tin (Sn), lead (Pb), silver (Ag), and/or copper (Cu)). The sintering process can include fusing materials together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys.

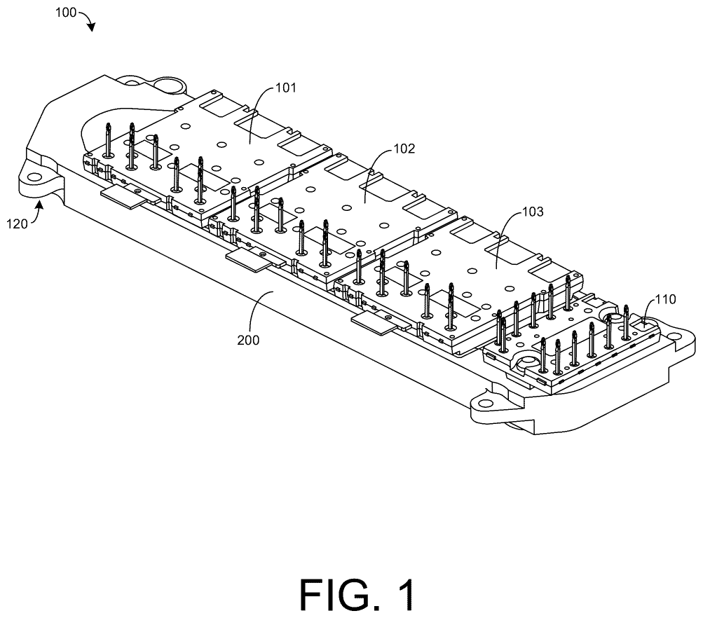

FIG. 1 is a perspective view of a system 100 including power modules and a cooling apparatus according to a possible implementation of the present disclosure. As shown, the plurality of modules can include a first power module 101, a second power module 102, and a third power module 103. Each of the power modules can be nominally the same (i.e., based on a common design) and can include power electronics configured for high voltages (e.g., >100 Volts) and high currents (e.g., >20 Amps).

In a possible implementation, the system 100 is an inverter (e.g., a three-phase inverter) and each power module is configured to receive a direct current (DC) voltage and further configured to output an alternating current (AC) signal corresponding to one of the three phases. In a possible implementation, the input of the power modules is coupled to a battery of an electric vehicle and the outputs of the power modules are coupled to windings of a motor (e.g., traction motor) of an electric vehicle (EV). In a possible implementation, each power module includes a half-bridge circuit comprising two transistors connected in series across the DC voltage.

The system 100 may further include an auxiliary module 110 (or modules), which may, or may not, include power electronics. In a possible implementation, the auxiliary module 110 is an exciter module configured to generate a stationary (DC) magnetic field for the motor of an electric vehicle. In some implementations, the system 100 can include more or less power modules than shown in FIG. 1. In some implementations, the auxiliary module 110 can be excluded.

In some implementations, the auxiliary module 110 can have a size (e.g., a footprint when viewed from above) and/or shape (e.g., thickness, width, length) that is different than a size and/or shape of one or more of the power modules, 101, 102, and 103. In some implementations, one or more of the power modules 101, 102, and 103 can have an identical or different size and/or shape. For example, the power module 101 can have a size and shape that is identical to a size and shape of the power module 102. As another example, the power module 101 can have a size and/or shape that is different from a size and/or shape of the power module 102.

The system 100 further includes a cooling apparatus 200 coupled to the power modules (and the auxiliary module 110). The cooling apparatus 200 can include an input opening (not shown) configured to receive a fluid (e.g., a fluid under pressure) and an output opening (not shown) configured to output the fluid (e.g., the fluid under pressure). In a possible implementation, the input opening and the output opening of the cooling apparatus 200 can be coupled to a cooling system (e.g., fluid pump, radiator, etc.) of the electric vehicle.

The cooling apparatus 200 can be shaped to support the power modules being arranged in a row. Accordingly, a length of the cooling apparatus 200 can be greater than a length of each power module (e.g., 250 mm) and a width of the cooling apparatus 200 can be approximately equal to a width of each power module (e.g., 60 mm). In a possible implementation, the first power module 101, second power module 102, and third power module 103 are coupled to a top surface of the cooling apparatus 200, while the input opening and the output opening are in a bottom surface of the cooling apparatus 200. In a possible implementation, the cooling apparatus can include a plurality of mounting features to integrate (i.e., connect) the cooling apparatus to the electric vehicle.

In a possible implementation, each mounting feature 120 includes a flange having an opening (e.g., an opening therethrough) configured to receive a fastener (e.g., screw). In some implementations, the mounting feature 120 can be configured to receive a variety of coupling elements such as a clip, a press-fit fitting, a rivet, and/or so forth. In some implementations, the cooling apparatus 200 can include more or less mounting features than shown in FIG. 1. In some implementations, the mounting feature 120 can be a tab.

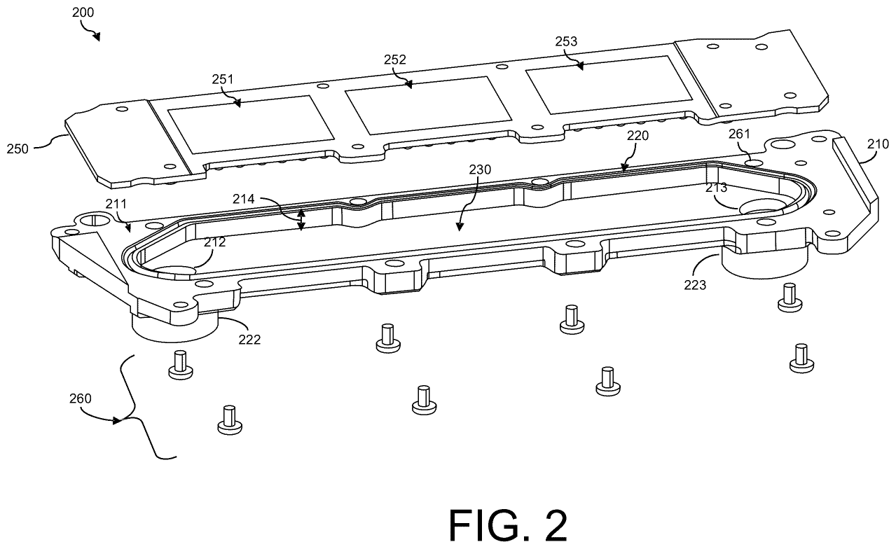

FIG. 2 is an exploded, perspective view of the cooling apparatus 200 according to a possible implementation of the present disclosure. FIG. 2 is oriented so that features (e.g., surfaces) described as being “top”, “above”, “upper”, etc. are closer to the top of the page than features described as being “bottom”, “below”, “lower”, etc. Additionally, features (e.g., edges) that are described as being “inner” are closer to the center of the page than features described as being “outer”. This convention is used throughout the figures unless otherwise described.

As shown in FIG. 2, the cooling apparatus 200 includes a body 210 and a cover 250. A bottom surface of the cover 250 faces (e.g., is exposed to) a top surface 211 of the body 210. A top surface of the cover 250 can include a plurality of raised areas for interfacing (e.g., thermally) with pads of the plurality of power modules. For example, a first raised area 251, a second raised area 252, and a third raised area 253 may each be configured to attach to corresponding pads on the bottom surfaces of the first power module 101, the second power module 102, and the third power module 103, respectively. In a possible implementation, the attachment may include soldering or sintering the pads of the power modules to the raised areas of the cover 250. In some implementations, one or more of the raised areas 251, 252, and 253 can be planar, with one or more channels or recesses around the raised areas 251, 252, and 253 such that they are raised relative to the channel.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

The body 210 of the cooling apparatus 200 includes a basin 230 (can also be referred to as a cavity) having a bottom surface offset from the top surface 211 by a depth 214. When the cover is attached to the body 210, the basin 230 and the cover 250 define a reservoir that is configured to contain a fluid (i.e., coolant). The fluid in the reservoir may flow between an input opening 212 in the bottom surface of the basin 230 and an output opening 213 in the bottom surface of the basin 230. The input opening 212 may allow the fluid to flow in from an input pipe-nipple 222 extending from a bottom surface of the body 210. Likewise, the output opening 213 may allow the fluid to flow out to an output pipe-nipple 223 extending from the bottom surface of the body 210. In a possible implementation, the input pipe-nipple 222 and the output pipe-nipple 223 may facilitate connection to cooling hoses of an electric vehicle.

The body 210 of the cooling apparatus 200 further includes a groove 220 in the top surface 211 that surrounds the basin 230. As shown in FIG. 2, the groove 220 can be uniformly offset from an outer edge of the basin 230 so that a portion of the top surface 211 is between the groove 220 and the basin 230. The groove 220 is configured to receive and contain an adhesive (e.g., sealant-adhesive) so that the cover 250 can be coupled (e.g., adhered) to the body 210 using the adhesive (e.g., sealant-adhesive) disposed in the groove 220. The adhesive (e.g., sealant-adhesive) and the groove 220 may also provide a seal so that the fluid does not leak from the reservoir. Accordingly, the adhesive (e.g., sealant-adhesive) may have a bonding strength sufficient to withstand a pressure of the fluid used to create a flow rate (e.g., 5-10 L/min) for cooling.

In some implementations, the groove 220 can be continuous around the basin 230. In some implementations, the groove 220 may not be continuous around the basin 230.

In a possible implementation, the cover 250 can be further attached to the body 210 using fasteners (e.g., screws 260). Accordingly, the body 210 may include openings that provide clearance for threaded portions of screws 260, while the cover 250 may include threaded openings to mate with the threads of the screws 260. As shown, in FIG. 2, each opening 261 may be located between an outer edge of the groove 220 and an outer edge of top surface 211. The seal created by the adhesive (e.g., sealant-adhesive) and screws 260 may be stronger than a seal created by an O-ring and fasteners. As a result, the cooling apparatus 200 may not include an O-ring.

In some implementations, one or more of the fasteners can be referred to as a coupling mechanism. In some implementations, although illustrated as a screw 260 by way of example, one or more of the fasteners can be, for example, a clip, a screw, a press fit fitting, a rivet, and/or so forth.

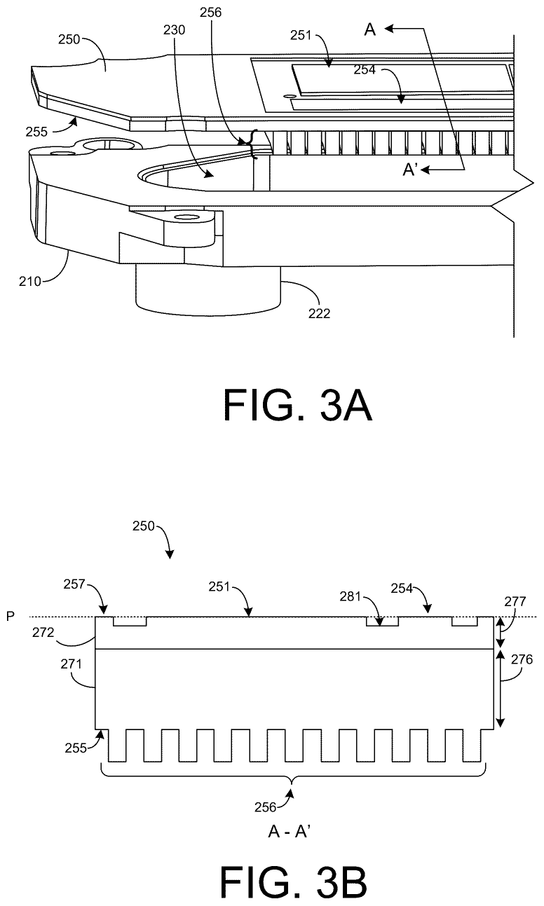

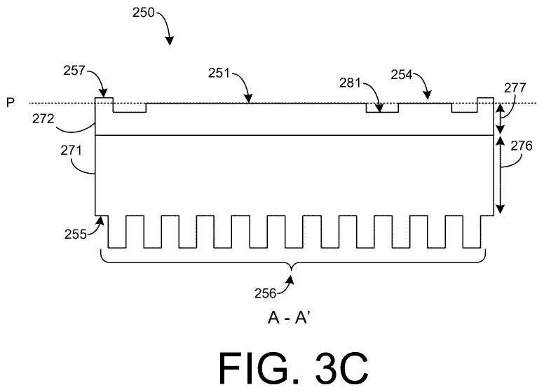

FIG. 3A is an exploded, side view of a portion of a cooling apparatus according to a possible implementation of the present disclosure. As shown, the cover 250 can include a plurality of pins 256. The plurality of pins 256 can be the same size (e.g., height, diameter) or different sizes. The plurality of pins 256 can have circular or non-circular cross sections. The plurality of pins 256 can be arranged in one or more patterns (e.g., grid, offset grid). The plurality of pins 256 are configured to extend from a bottom surface 255 of the cover 250 and into the basin 230 (i.e., reservoir) when the cover 250 is attached to the body 210. As a result, the plurality of pins 256 can increase a surface area of the cover that is in contact with the fluid. The increased surface area can increase the thermal conductivity of a thermal path from the power module to the fluid, through the cover.

As shown in FIG. 3A, the cover 250 further includes a second raised area 254 for each power module to illustrate that each power module may include multiple pads for connection to the cover 250. In a possible implementation, portions of the top surface of the cover 250 are removed to define the raised areas. In other words, the raised areas (i.e., plateau areas, pedestal areas) can be created by removing portions of the cover 250 surrounding the raised areas. For example, portions of the cover 250 can be removed, which can form one or more channels 281, at least partially, or entirely, around the raised areas so that the raised areas are defined. Said another way, the raised areas can be mesas that are defined by one or more recesses within the cover 250. The one or more recesses can be at least partially, or entirely, around the raised areas.

The raised areas may be shaped (e.g., rectangular) and sized to match pads of the power modules and may be plated with one or more metals to facilitate soldering or sintering. In a possible implementation, the raised areas may be plated with a nickel layer to prevent corrosion. In a possible implementation, a silver layer may be plated over the nickel layer (e.g., in the raised areas) to facilitate soldering.

FIG. 3B is a cross-sectional view of the cover shown in FIG. 3A according to a possible implementation of the present disclosure. As shown in FIG. 3B, the cover 250 of the cooling apparatus may include a first material layer and a second material layer. The material layers may be different materials (e.g., different metals) selected thermal conductivity with weight for a particular application (e.g., electric vehicle).

As shown in FIG. 3B, the cover 250 can include a first metal layer 271 (i.e. bottom metal layer), which is configured to face the basin 230 when the cover 250 is attached to the body 210. The cover 250 can further include a second metal layer 272 (i.e., top metal layer) that is configured to face the power modules when the power modules are attached to the cover 250. The cover 250 includes raised areas 251 and 254. As shown, the layers are arranged in a vertical stack so that the bottom surface of the second metal layer 272 is in contact with the top surface of the first metal layer 271. The metal layers can be connected to form a monolithic cover using one or more processes, which can include one or more of a plating process, a cladding process, a sintering process, and/or a sputtering process. For example, pressure and heat may be applied for a period to attach the metal layers.

As shown in FIG. 3B, the first metal layer 271 has a first thickness 276, and the second metal layer 272 has a second thickness 277. In a first possible implementation, the first thickness 276 is greater than the second thickness 277. In a second possible implementation, the first thickness 276 is less than the second thickness 277. In a third possible implementation, the first thickness 276 is equal to the second thickness 277.

In some implementations, the second thickness 277 can be 4 times thinner than the first thickness 276. In some implementations, the second thickness 277 can be less than 4 times thinner than the first thickness 276. In some implementations, the second thickness 277 can be greater than 4 times thinner than the first thickness 276.

In some implementations, the first thickness 277 can be 4 times thicker than the second thickness 277. In some implementations, the first thickness 277 can be less than 4 times thicker than the second thickness 277. In some implementations, the first thickness 277 can be more than 4 times thicker than the second thickness 277.

The thicknesses of each layer may be based on a desired weight of the cover 250 and on one or more desired thermal properties of the cover 250 (e.g., thermal resistance, thermal conductivity, heat capacity, coefficient of thermal expansion (CTE), etc.). In a possible implementation, the thickness of each layer is selected so that the weight of the cover 250 is minimized for a particular thermal conductivity.

As shown in FIG. 3B, the raised area 251 is planar (along plane A) with the raised area 254 and other parts of the cover 250. In some implementations, the raised area 254 can be higher than the raised area 251. In some implementations, the raised area 254 can be lower than the raised area 251. In some implementations, raised area 251 and the raised area 254 can be lower than other portions of the cover 250.

In some implementations, raised area 251 and/or the raised area 254 can be lower or higher than other portions (e.g., side portion 257) of the cover 250. This example implementation is shown in at least FIG. 3C. In the implementation shown in FIG. 3C, the portion 257 has a height that is different than the height of the raised area 251 and/or the raised area 254. The raised area 251 and/or the raised area 254 have a different height than a bottom surface of the channel 281.

In some implementations, a thickness of the portion 257 above the plane P can be different than (e.g., greater than or less than) a depth of the channel 281 below the plane P. In some implementations, a thickness of the portion 257 above the plane P can be the same as a depth of the channel 281 below the plane P.

In some implementations, the first metal layer 271 can be a metal that is different than a metal of the second metal layer 272. In a possible implementation, the first metal layer 271 (i.e. bottom metal layer) is aluminum (Al), and the second metal layer 272 (i.e., top metal layer) is copper (Cu). The aluminum layer (i.e., first thickness 276) may be thicker than the copper layer (i.e., second thickness 277) to reduce the weight of the cover 250, which can reduce the overall weight of the system 100 (see FIG. 1). As shown, the plurality of pins 256 extend from a bottom surface 255 of the first metal layer 271.

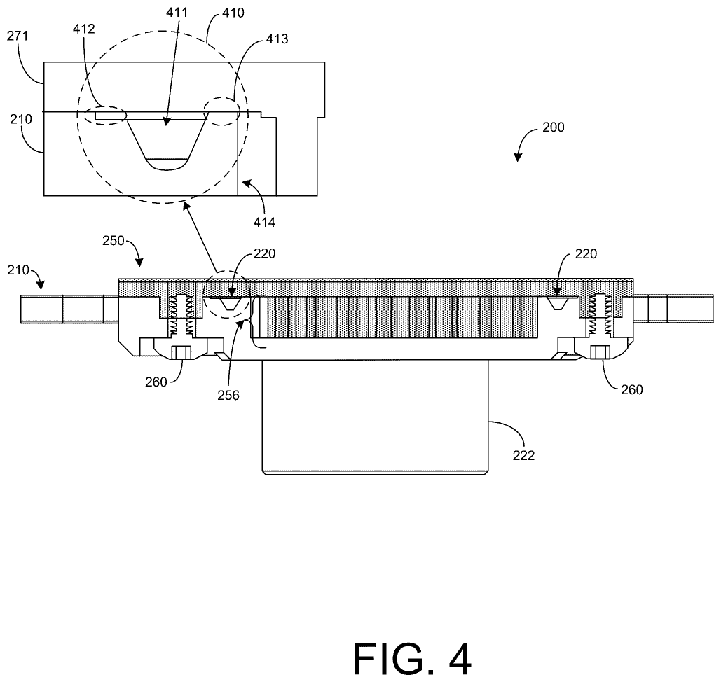

FIG. 4 is a cross-sectional view of the cooling apparatus 200 with an inset illustrating details of the groove 220 for adhesive (e.g., sealant-adhesive) according to a possible implementation of the present disclosure. As described previously, the cover 250 can include first metal layer 271 facing the reservoir and a second metal layer 272, to which a power module (or power modules) can be attached. In a possible implementation, the body 210 is the same material as one of the metal layers (e.g. AL). In another possible implementation, the body 210 can be a different material. For example, the body may be a non-metallic material, including (but not limited to) ceramic, FR4, phenolics, fiber glass, graphite, or some combination thereof.

FIG. 4 includes an inset 410 illustrating a cross section of the groove. As shown, the cross section of the groove 220 can include a dispense portion 411, which is configured to receive an adhesive (e.g., sealant-adhesive). The dispense portion 411 can be conical in shape to form a conical gap between the first metal layer 271 (i.e., bottom metal layer) of the cover and the body 210. The adhesive (e.g., sealant-adhesive) can be disposed into the dispense portion 411 using a variety of dispense methods including (but not limited to) needle dispensing, nozzle dispensing, and jet dispensing.

The amount of adhesive dispensed can be selected so that the adhesive connects the first metal layer 271 to the body 210 when the cover is attached to the body. To accommodate variations in the amount, the cross section of the groove 220 may include an overflow portion 412. The overflow portion 412 can be rectangular in shape to form a rectangular gap between the first metal layer 271 (i.e., bottom metal layer) of the cover and the body 210. The adhesive (e.g., sealant-adhesive) can occupy (e.g., can be pushed into) the overflow portion 412 when the cover 250 is connected to the body 210 (e.g., using screws 260).

As shown, the cross section of the groove 220 can be offset from an outer edge 414 of the basin to form a sealing portion 413 of the groove 220. In the sealing portion 413, the top surface of the body 210 is in direct contact with the first metal layer 271 of the cover 250. The sealing portion may create a seal so that the fluid, which can be under pressure, does not leak out of the reservoir and so that the adhesive-sealant does not enter the reservoir. This seal may be strengthened by a connecting force resulting from the screws 260 and the adhesive (e.g., sealant-adhesive).

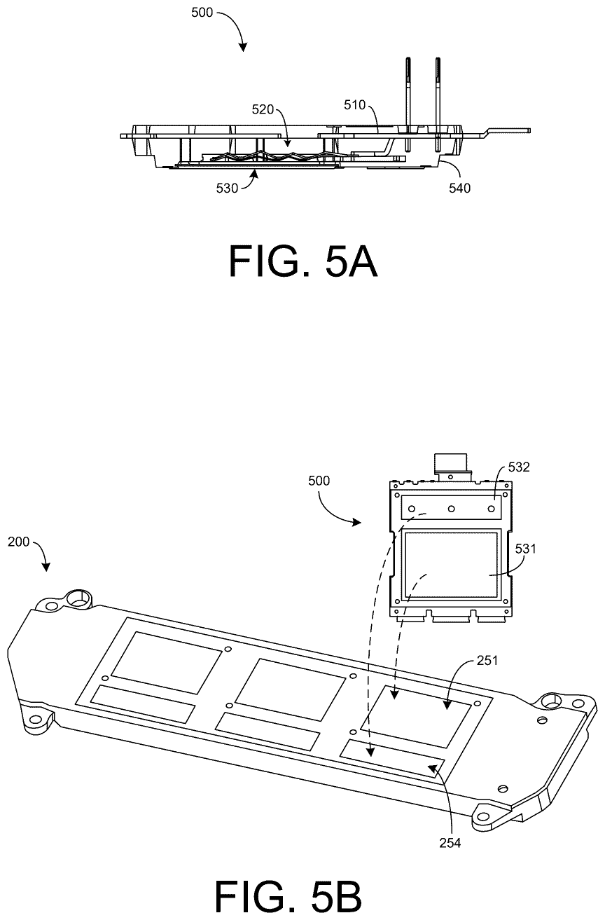

FIG. 5A is a side-view of a power module according to a possible implementation of the present disclosure. The power module 500 may include multiple dies 520, which can be electrically coupled to a substrate 530. The substrate 530 can include conductors (e.g., traces, pads, wires, vias etc.) to form the electrical connections required to form a circuit (e.g., half-bridge circuit), to connect to a lead frame 510 for external electrical connection, and to provide a thermal connection to the cooling apparatus. The lead frame, the dies, and the substrate may be encapsulated by encapsulation material 540. In a possible implementation, the encapsulation material may include openings to expose pads on a bottom surface of the power module. In a possible implementation, the bottom surface of the power module 500 includes a first pad 531 and a second pad 532.

As noted above, the power module 500 can include one or more DBM substrates. A surface of one or more of the DBM substrates can be exposed through the power module as the first pad 531 and/or the second pad 532.

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

In some implementations, one or more of the power modules can include one or more lead frame structures. Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

The power modules described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the power module implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a separate module (e.g., a package including a semiconductor device) can be included in one or more of the power modules. The power module can be referred to as a package. For example, one or more modules can be one or more sub modules included within the power module. In other words, a first module can be included as a sub module within a second module.

FIG. 5B illustrates the placement of the power module 500 on the cooling apparatus 200 according to a possible implementation of the present disclosure. As shown, the first pad 531 may be positioned on the first raised area 251 and the second pad 532 may be positioned on the second raised area 254 in order to make a mechanical (and electrical) connection. In a possible implementation, the first pad 531 and the second pad 532 are copper pads. The mechanical connection may include fusing pads and the raised areas using a soldering process, a sintering process, or a bonding process.

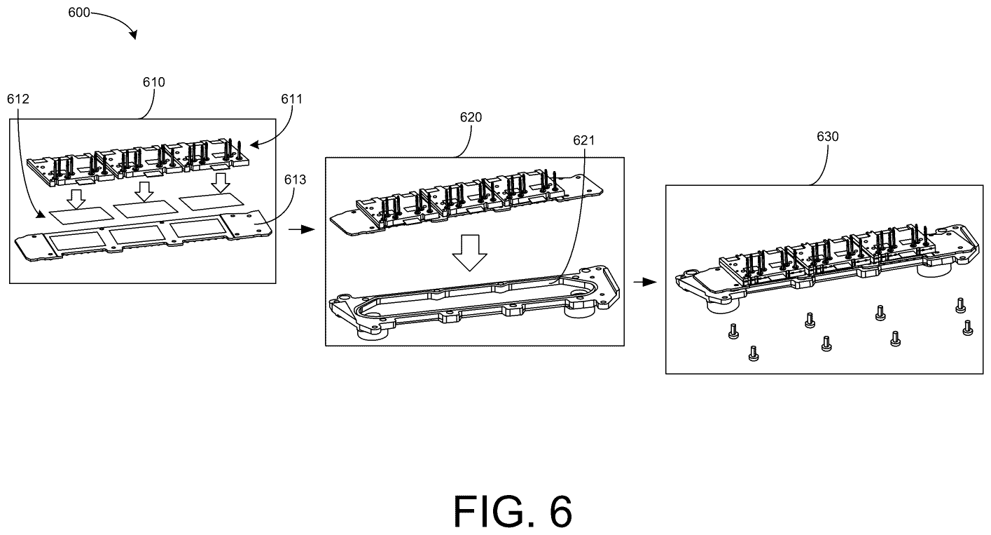

FIG. 6 visually illustrates a method for assembling a three-phase inverter with a cooling apparatus according to a possible implementation of the present disclosure. The method 600 includes attaching 610 power modules 611 to a cover 613. Attaching the power modules 611 to the cover 613 may include positioning attachment material 612 between each power module and a raised area of the cover 613. In a possible implementation, the attachment material is a solder paste. In a possible implementation the top side of the cover 613 is a copper layer that is plated with at least silver in at least the areas of the attachment material.

The method 600 further includes dispensing an adhesive (e.g., sealant-adhesive) into a groove in a top surface of the body 621 and adhering 620 the bottom side of the cover 613 to the top surface of the body 621 using the adhesive (e.g., sealant-adhesive). In a possible implementation, adhering includes applying pressure and heat to the interface between the cover and the body to create a bond (e.g., cure the adhesive).

The method 600 can further include fastening 630 the cover to the body using a plurality of screws. The fastening may increase the strength of the connection between the cover and the body.

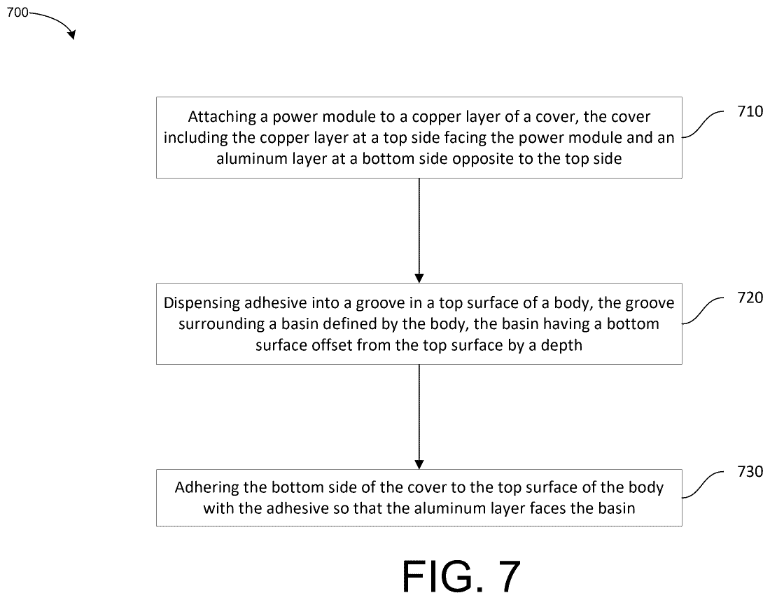

FIG. 7 is a flowchart of an example method for assembling the three-phase inverter with the cooling apparatus. The method 700 includes attaching 710 a power module to a cover. The cover includes a copper layer at a top side facing the power module and an aluminum layer at a bottom side opposite to the top side. The method 700 further includes dispensing 720 adhesive into a groove in a top surface of a body, the groove surrounding a basin defined by the body, the basin having a bottom surface offset from the top surface by a depth. The method 700 further includes adhering 730 the bottom side of the cover to the top surface of the body with the adhesive so that the aluminum layer faces the basin.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

1. A cooling apparatus for a power module, the cooling apparatus comprising:
a body including:
a basin having a bottom surface offset from a top surface by a depth; and
a cover coupled to the top surface of the body by an adhesive, the cover including:
a first material layer facing the basin; and
a second material layer facing the power module.

2. The cooling apparatus according to claim 1, further comprising a groove in the top surface that surrounds at least a portion of the basin, the adhesive disposed in the groove.

3. The cooling apparatus according to claim 2, wherein:
the groove is uniformly offset from an outer edge of the basin so that a portion of the top surface is between the groove and the basin.

4. The cooling apparatus according to claim 2, wherein the groove defines a cross section including:
an overflow portion forming a rectangular gap between the first material layer and the body; and
a dispense portion forming a conical gap between the first material layer and the body.

5. The cooling apparatus according to claim 1, wherein the basin and the cover define a reservoir, the reservoir configured to contain a fluid, the fluid flowing between an input opening in the bottom surface and an output opening in the bottom surface.

6. The cooling apparatus according to claim 5, wherein the cover further includes:
a plurality of pins extending from the first material layer into the reservoir.

7. The cooling apparatus according to claim 1, wherein:
the first material layer is an aluminum layer; and
the second material layer is a copper layer.

8. The cooling apparatus according to claim 7, wherein the aluminum layer is thicker than the copper layer to reduce a weight of the cooling apparatus.

9. The cooling apparatus according to claim 7, wherein the copper layer is plated with nickel on a surface facing the power module.

10. The cooling apparatus according to claim 1, wherein the second material layer is a copper layer that includes a raised area that matches a size and a shape of a pad on the power module.

11. The cooling apparatus according to claim 10, wherein the raised area is plated with nickel and silver so that the pad of the power module can be soldered or sintered to the raised area.

12. The cooling apparatus according to claim 1, further comprising:
at least one fastener configured to attach the cover to the body.

13. An inverter comprising:
a first power module;
a second power module; and
a cooler coupled to the first power module, and the second power module, the cooler including:
a body including:
a basin having a bottom surface offset from a top surface by a depth; and
a groove in the top surface surrounding the basin; and
a cover adhered to the top surface of the body by an adhesive disposed in the groove, the cover including:
a first metal layer facing the basin; and
a second metal layer facing the first power module and the second power module.

14. The inverter according to claim 13, wherein the basin and the cover define a reservoir configured to contain a fluid flowing between an input opening in the bottom surface and an output opening in the bottom surface.

15. The inverter according to claim 14, wherein the first metal layer includes a plurality of pins extending from the first metal layer into the reservoir.

16. The inverter according to claim 13, wherein the groove defines a cross section including:
an overflow portion forming a rectangular gap between the first metal layer and the body; and
a dispense portion forming a conical gap between the first metal layer and the body.

17. The inverter according to claim 13, wherein the first metal layer is an aluminum layer and the second metal layer is a copper layer, the aluminum layer being thicker than the copper layer to reduce a weight of the inverter.

18. A method comprising:
attaching a power module to a copper layer of a cover, the cover including the copper layer at a top side facing the power module and an aluminum layer at a bottom side opposite to the top side;
dispensing adhesive into a groove in a top surface of a body, the groove surrounding a basin defined by the body, the basin having a bottom surface offset from the top surface by a depth; and
adhering the bottom side of the cover to the top surface of the body with the adhesive so that the aluminum layer faces the basin.

19. The method according to claim 18, further comprising:
applying pressure and heat for a period to clad the copper layer to the aluminum layer.

20. The method according to claim 18, further comprising:
plating the copper layer with one or more other metal layers before attaching the power module.
